(19) United States
(12) Patent Application Publication
(10) Pub. No.: US 2011/0176573 A1
(43) Pub. Date: Jul. 21, 2011

(54) Silicone Leaded Chip Carrier

(75) Inventors: Kheng Leng Tan, Gelugor (MY); Keat Chuan Ng, Bayan Lepas (MY); Kee Hon Lee, Kuala Lumpur (MY)

(73) Assignee: Avago Technologies ECBU IP (Singapore) Pte. Ltd., Singapore (SG)

(21) Appl. No.: 13/075,866

(22) Filed: Mar. 30, 2011

Related U.S. Application Data
(62) Division of application No. 12/466,329, filed on May 14, 2009.

(51) Int. Cl. H01S 5/022; H01L 33/60

(52) U.S. Cl. 372/50.1; 257/98; 257/E33.072

(57) ABSTRACT

In an embodiment, the invention provides a SLCC package comprising first and second electrically conductive terminals, a polysiloxane and glass fiber structural body, a light source and a polysiloxane encapsulant. The first and second electrically conductive terminals are attached to the polysiloxane and glass fiber structural body. The light source is electrically connected to the first and second electrically conductive terminals. The polysiloxane and glass fiber structural body has a cavity that contains at least a portion of the polysiloxane encapsulant.

### RELATED APPLICATION

This is a divisional of co-pending application Ser. No. 12/466,329, filed on May 14, 2009, the entire disclosure of which is incorporated into this application by reference.

### BACKGROUND

Light emitting diodes (LEDs) have many advantages over conventional light sources, such as incandescent, halogen and fluorescent lamps. These advantages include longer operating life, lower power consumption and smaller size. Consequently, conventional light sources are increasingly being replaced with LEDs in traditional lighting applications. As an example, LEDs are currently being used in flashlights, traffic signal lights, automotive taillights and display devices.

Among the various packages for LEDs, an LED package of interest is the plastic leaded chip carrier (PLCC) package for a surface mount LED. Surface mount LEDs in PLCC packages may be used, for example, in automotive interior display devices, electronic signs and signals, and electrical equipment.

A concern with the current process for producing PLCC packages is the problem of thermal expansion between different materials used in PLCC packages. Because materials expand and contract differently, thermal stress is created between different materials. A coefficient of thermal expansion (CTE) is often used to characterize how different materials expand or contract with changes in temperature.

Thermal stress may initiate mini cracks along interfacial surfaces. Thermal stress may also cause de-lamination between a die and a lead frame for example. Thermal cycling conditions (i.e. repeated changes in temperature) that occur during normal operation may propagate mini cracks to the extent a die that is attached to a lead frame may be lifted from the lead frame.

Silicone may be used as a material to encapsulate a light source in a PLCC because it is soft and pliable. Because silicone is soft and pliable, it is often used to reduce cracks in a PLCC package.

### BRIEF DESCRIPTION OF THE DRAWINGS

FIG. 1 is a sectional view of a SLCC (silicone leaded chip carrier) package in accordance with an exemplary embodiment of the invention.

FIG. 2 is a sectional view of a SLCC (silicone leaded chip carrier) package in accordance with an exemplary embodiment of the invention.

FIG. 3 is a flow diagram of a process for manufacturing a SLCC package in accordance with an embodiment of the invention.

FIG. 4 is a flow diagram of a process for manufacturing a SLCC package in accordance with an embodiment of the invention.

### DETAILED DESCRIPTION

The drawings and description, in general, disclose a SLCC (silicone leaded chip carrier) package 100 containing a structural body 102, an encapsulant 108, electrically conductive terminals 104 and 106, a light source 112 and wire bonds 110. The structural body 102 and the encapsulant 108 comprise silicone based materials. Because the structural body 102 and the encapsulant 108 are comprised of a silicone based material, a CTE mismatch between the structural body 102 and the encapsulant 108 is reduced. As result, the encapsulant 108 and the structural body 102 will be less likely to cause problems related to thermal stress.

For example, the occurrence of de-lamination between the light source 112 and the electrically conducting terminals 104 and 106 due to a CTE mismatch between the encapsulant 108 and the structural body 102 will be less likely.

In a first exemplary embodiment, the structural body 102 comprises polysiloxane and glass fibers. One reason for adding glass fibers to polysiloxane is to increase the strength and rigidity of the structural body 102. Silicone based materials without glass fibers tend to be soft and pliable. In this first exemplary embodiment, the structural body 102 comprises about 15-35 percent by weight glass fibers. Polysiloxane usually does not chemically react with glass fibers. The encapsulant 108 in this first exemplary embodiment comprises polysiloxane. Glass fibers are not usually contained in the encapsulant 108 because the encapsulant 108 usually does not provide structural support and the encapsulant 108 should remain translucent or transparent.

In a second exemplary embodiment, the structural body 102 comprises polysiloxane, glass fibers and at least one reflective agent. One reason for adding a reflective agent to polysiloxane is to increase the reflectivity of the structural body 102. Increasing the reflectivity of the structural body 102 improves the efficiency of light emitted from a SLCC package 100. The reflective agent may also be used to create a white structural body 102.

In this second exemplary embodiment, the structural body 102 comprises no more than 20 percent by weight reflective agent. Polysiloxane usually does not chemically react with reflective agents. TiO₂, Al₂O₃ and SiO₂ are examples of reflective agents; however other reflective agents may be used. In this second exemplary embodiment the encapsulant 108 comprises polysiloxane. However, in other embodiments the encapsulant 108 may contain reflective agents. Adding a reflective agent to the encapsulant can act as a diffusant to diffuse the light output pattern from the light source 112.

In a third exemplary embodiment, the structural body 102 comprises polysiloxane, glass fibers and an adhesion promoter. Adding an adhesion promoter improves the adhesion between the structural body 102 and the encapsulant 108. In this third exemplary embodiment, silane may be used as an adhesion promoter. Also in this third exemplary embodiment, the encapsulant 108 comprises at least polysiloxane and an adhesion promoter.

In this third exemplary embodiment, the general structure for silane is (RO)₃SiCH₂CH₂CH₂—X. RO is a hydrolysable group such as methoxy, ethoxy and acetoxy. X is an organofunctional group such as amino, methacryloxy and epoxy. Silanes include, but are not limited to, tetraethoxysilane, methyltrimethoxysilane, propyltriethoxysilane, isobutyltrimethoxysilane and phenyltrimethoxysilane.

In this third exemplary embodiment, the structural body 102 comprises no more than 10 percent by weight silane. In this third exemplary embodiment the encapsulant 108 comprises no more than 10 percent by weight silane. Adding silane to the encapsulant 108 does not significantly reduce the encapsulants translucency or transparency.

In a fourth exemplary embodiment the encapsulant 108 comprises at least polysiloxane and diffussants and/or phosphors. Phosphors, for example, may be added as wavelength converters. When light of a first wavelength strikes a phosphor particle, light of a second wavelength is created.

In these four exemplary embodiments, the structural body 102 and the encapsulant 108 are made of silicone based materials. Because the structural body 102 and the encapsulant 108 are made of silicone based materials, a CTE mismatch between the encapsulant 108 and the structural body 102 will be less likely to cause problems related to thermal stress. For example, the occurrence of de-lamination between the light source 112 and the electrically conductive terminal 104 due to a CTE mismatch between the encapsulant 108 and the structural body 102 will be less likely.

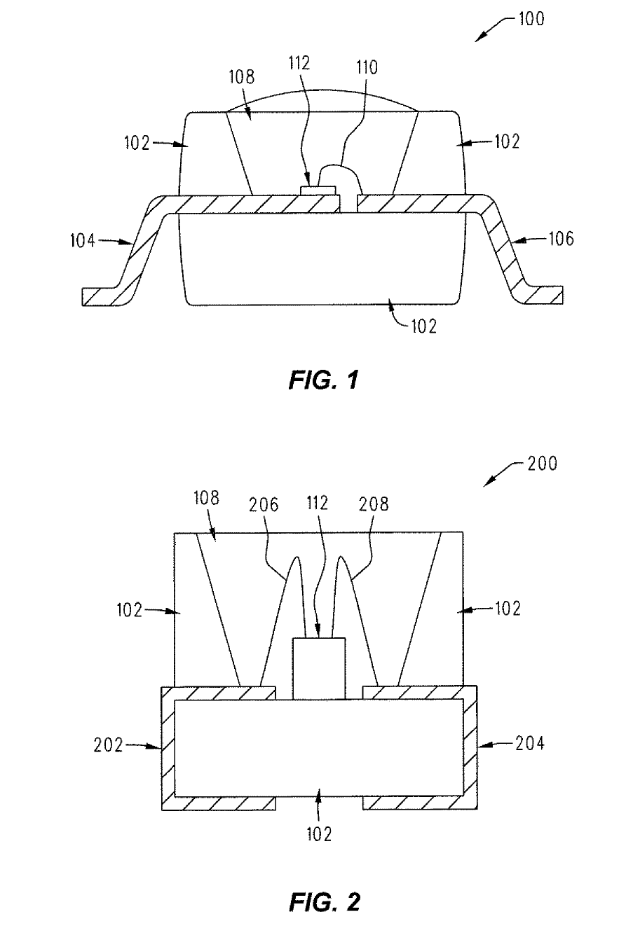

FIG. 1 is a sectional view of a SLCC (silicone leaded chip carrier) package 100 in accordance with an exemplary embodiment of the invention. In this exemplary embodiment, the first lead frame 104 and the second lead frame 106 have gull wing leads. However, it is anticipated that other leads such as SOJ leads, J-leads, reverse gull wing leads and straight cut leads may be used in other embodiments of this invention. The first 104 and 106 lead frames also function as heat sinks for the SLCC package 100.

The structural body 102 shown in FIG. 1 contains a cavity. In this exemplary embodiment, the cavity may be used to contain a portion of encapsulant 108. In one embodiment, the structural body 102 may be an integral single piece structure. In another embodiment the structural body 102 may have dimensions that conform to the PLCC-4 standard. The structural body 102 may be formed, for example, using a transfer molding process. The cavity formed by the structural body 102 may be filled, for example, using injection molding, transfer molding, and compression molding.

In FIG. 1, a light source 112 is physically and electrically connected to lead frame 104. The light source 112 may, for example, be an LED or a semiconductor laser. Electromagnetic radiation emitted from the light source 112 may be visible light, ultra-violet light or infra-red light. In this exemplary embodiment, a wire bond 110 electrically connects the light source 112 to lead frame 106. In another exemplary embodiment, an optical lens (not shown) may be formed as an integral part of the encapsulant 108.

FIG. 2 is a sectional view of a SLCC (silicone leaded chip carrier) package 200 in accordance with an exemplary embodiment of the invention. In this exemplary embodiment, the first electrically conductive terminal 202 and the second electrically conductive terminal 204 are electro-plated traces. The first 202 and second 204 electro-plated traces also function as heat sinks for the SLCC package 200.

The structural body 102 shown in FIG. 2 contains a cavity. In this exemplary embodiment, the cavity may be used to contain a portion of encapsulant 108. In one embodiment, the structural body 102 may be an integral single piece structure. The structural body 102 may be formed, for example, using a transfer molding process. The cavity formed by the structural body 102 may be filled, for example, using injection molding, transfer molding, and compression molding.

In FIG. 2, a light source 112 is physically mounted to the structural body 102. The light source 112 may, for example, be an LED or a semiconductor laser. In this exemplary embodiment, a wire bond 206 electrically connects the light source 112 to electro-plated trace 202 and a wire bond 208 electrically connects the light source 112 to electro-plated trace 204. In another exemplary embodiment, an optical lens (not shown) may be formed as an integral part of the encapsulant 108.

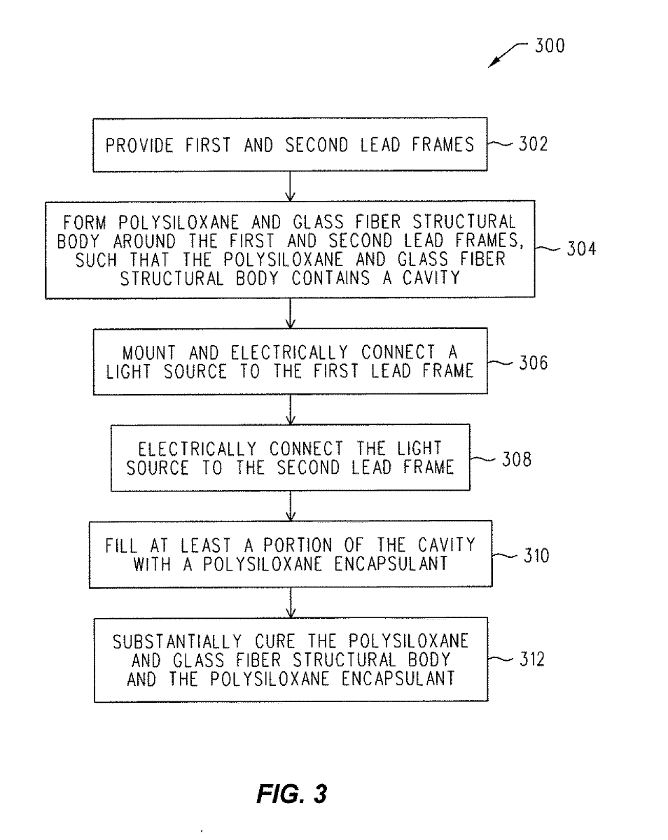

FIG. 3 is a flow diagram 300 of a process for manufacturing a SLCC package in accordance with an embodiment of the invention. In this exemplary embodiment, a first 104 and a second 106 lead frame are provided as shown in box 302. Next as shown in box 304 a polysiloxane and glass fiber structural body 102 is formed around the first 104 and second 106 lead frames. In another exemplary embodiment, the structural body 102 may comprise polysiloxane, glass fibers, a reflective agent and silane. In this exemplary embodiment, the polysiloxane and glass fiber structural body 102 is an integral single piece structure having a cavity that serves as a container for containing at least a portion of the encapsulant 108.

Next as shown in box 306 a light source 112 is mounted and electrically connected to the first lead frame 104. Next as shown in box 308 an electrical connection is made from the light source 112 to the second lead frame 106. In this exemplary embodiment, a wire bond 110 is used to make the electrical connection from the light source 112 to the second lead frame 106.

Next as shown in box 310 an encapsuiant 108 fills at least a portion of the cavity. The encapsulant 108, in this example, comprises polysiloxane. In another embodiment, the encapsulant 108 may comprise polysiloxane and silane. In this exemplary embodiment, the encapsulant 108 is an integral single piece structure. In another exemplary embodiment, an optical lens (not shown) may be formed as an integral part of the encapsulant 108.

Next as shown in box 312, the polysiloxane and glass fiber structural body 102 and the polysiloxane encapsulant 108 are cured. For example, a full cure may be obtained at around 150 degrees centigrade. The amount of time required to fully cure the polysiloxane and glass fiber structural body 102 and the polysiloxane encapsulant 108 varies between 2-8 hours depending on the composition of the structural body 102 and the encapsulant 108.

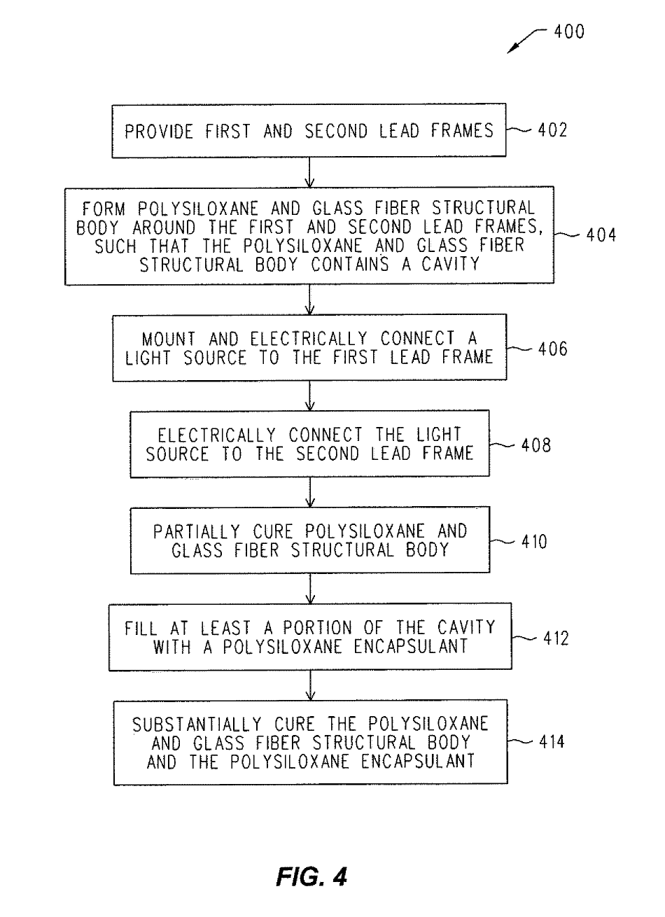

FIG. 4 is a flow diagram 400 of a process for manufacturing a SLCC package in accordance with an embodiment of the invention. In this exemplary embodiment, a first 104 and a second 106 lead frame are provided as shown in box 402. Next as shown in box 404 a polysiloxane and glass fiber structural body 102 is formed around the first 104 and second 106 lead frames. In another exemplary embodiment, the structural body 102 may comprise polysiloxane, glass fibers, a reflective agent and silane. In this exemplary embodiment, the polysiloxane and glass fiber structural body 102 is an integral single piece structure having a cavity that serves as a container for containing at least a portion of the encapsulant 108.

Next as shown in box 406 a light source 112 is mounted and electrically connected to the first lead frame 104. Next as shown in box 408 an electrical connection is made from the light source 112 to the second lead frame 106. In this exemplary embodiment, a wire bond 110 is used to make the electrical connection from the light source 112 to the second lead frame 106.

Next as shown in box 410, the polysiloxane and glass fiber structural body 102 is partially cured. For example, a partial cure may be obtained at around 60-80 degrees centigrade. The amount of time required to partially cure the polysiloxane and glass fiber structural body 102 varies between 2-3 hours depending on the composition of the structural body 102.

Next as shown in box 412 an encapsulant 108 fills at least a portion of the cavity. The encapsulant 108, in this example, comprises polysiloxane. In another embodiment, the encapsulant 108 may comprise polysiloxane and silane. In this exemplary embodiment, the encapsulant 108 is an integral single piece structure. In another exemplary embodiment, an optical lens (not shown) may be formed as an integral part of the encapsulant 108.

Next as shown in box 414, the polysiloxane and glass fiber structural body 102 and the polysiloxane encapsulant 108 are cured. For example, a full cure may be obtained at around 150 degrees centigrade. The amount of time required to fully cure the polysiloxane and glass fiber structural body 102 and the polysiloxane encapsulant 108 varies between 2-8 hours depending on the composition of the structural body 102 and the encapsulant 108.

The foregoing description has been presented for purposes of illustration and description. It is not intended to be exhaustive or to limit the invention to the precise form disclosed, and other modifications and variations may be possible in light of the above teachings. The exemplary embodiments were chosen and described in order to best explain the applicable principles and their practical application to thereby enable others skilled in the art to best utilize various embodiments and various modifications as are suited to the particular use contemplated. It is intended that the appended claims be construed to include other alternative embodiments except insofar as limited by the prior art.

What is claimed is:

1. A SLCC (silicone leaded chip carrier) package comprising:
a light source;
at least first and second electrically conductive terminals;
a structural body comprising polysiloxane and glass fibers;
an encapsulant comprising polysiloxane;
wherein the at least first and second conductive terminals are attached to the structural body;
wherein the at least first and second conductive terminals are electrically connected to the light source;
wherein the structural body has a cavity that contains a least a portion of the encapsulant.

2. The SLCC package of claim 1 wherein the structural body comprises about 15-35 percent by weight glass fibers.

3. The SLCC package of claim 1 wherein the structural body further comprises a reflective agent selected from a group consisting of TiO₂, Al₂O₃ and SiO₂.

4. The SLCC package of claim 3 wherein the structural body comprises no more than 20 percent by weight reflective agent.

5. The SLCC package of claim 1 wherein the structural body further comprises a silane selected from a group consisting of tetraethoxysilane, methyltrimethoxysilane, propyltriethoxysilane, isobutyltrimethoxysilane and phenyltrimethoxysilane.

6. The SLCC package of claim 5 wherein the structural body comprises no more than 10 percent by weight silane.

7. The SLCC package of claim 1 wherein the encapsulant further comprises a silane selected from a group consisting of tetraethoxysilane, methyltrimethoxysilane, propyltriethoxysilane, isobutyltrimethoxysilane and phenyltrimethoxysilane.

8. The SLCC package of claim 7 wherein the encapsulant comprises no more than 10 percent by weight silane.

9. The SLCC package of claim 1 wherein the encapsulant further comprises material selected from a group consisting of diffussants and phosphors.

10. The SLCC package of claim 1 wherein the structural body is an integral single piece structure.

11. The SLCC package of claim 1 wherein the at least first and second conductive terminals are lead frames.

12. The SLCC package of claim 1 wherein the at least first and second conductive terminals are electro-plated traces.

13. The SLCC package of claim 1 wherein the at least first and second conductive terminals are electrically connected to the light source by wire bonds.

14. The SLCC package of claim 11 wherein leads of the first and second lead frames includes leads selected from a group consisting of J leads, SOJ leads, gull wing leads, reverse gull wing leads and straight cut leads.

15. The SLCC package of claim 1 wherein the light source is selected from a group consisting of an LED and a laser.

16. The SLCC package of claim 1 wherein electromagnetic radiation emitted from the light source includes visible light, ultra-violet light and infra-red light.
